(19) United States
(12) Patent Application Publication
(10) Pub. No.: US 2012/0130669 A1
(43) Pub. Date: May 24, 2012

(54) VARIATION AWARE TESTING OF SMALL RANDOM DELAY DEFECTS

(75) Inventors: JINJUN XIONG, White Plains, NY (US); VLADIMIR ZOLOTOV, Putnam Valley, NY (US)

(73) Assignee: International Business Machines Corporation, Armonk, NY (US)

(21) Appl. No.: 12/953,727

(22) Filed: Nov. 24, 2010

(51) Int. Cl. G06F 17/18; G06F 19/00; G01R 31/00

(52) U.S. Cl. 702/117

(57) ABSTRACT

In one embodiment, the invention is a method and apparatus for variation aware testing of small random delay defects. One embodiment of a method for selecting a set of paths with which to test an integrated circuit chip includes computing a metric that considers the joint impact of parametric process variation delay defects and single random delay defects and selecting the set of paths such that the value of the metric is at least as great as a target value.

### BACKGROUND OF THE INVENTION

The present invention relates generally to design automation, and relates more particularly to path selection techniques for at-speed structural test (ASST) of integrated circuit (IC) chips.

When IC chips come off the manufacturing line, the chips are tested “at-speed” to ensure that they perform correctly (and to filter out chips that do not perform correctly). In particular, a set of paths is selected, and the set of paths is then tested for each chip in order to identify the chips in which one or more of the selected paths fail timing requirements. Typically, the most difficult defects to test are of two main types: parametric process variation delay defects that affect multiple cell and wire delays and small random delay defects that affect only a single cell or wire (but the location of this cell or wire can be distributed randomly anywhere on the chip). Both types of delay defects are present in manufactured chips, and it is the combined effects of both delay defects that cause chip performance to deviate from its nominal value. Because of these process variations and delay defects, different paths can be critical in different chips. That is, a path that is critical in one chip may not be critical in another chip, and vice versa. As such, selection of the paths that have a higher probability of being critical is typically a goal. Selection of paths that will cover testing for the joint impact of process variations and delay defects will result in better tests.

Existing solutions for testing delay defects do not typically account for process variations. For instance, some techniques test only for large transition delay defects and cannot be used efficiently to test for small random delay defects or process variation delay defects. Other techniques test for small random delay defects but do not consider process variations. These techniques cannot be used efficiently to test for the combination of process variations and small random delay defects and also do not consider the fact that process variations may actually bide small random delay defects (i.e., mask the impact of the existence of a small random delay defect).

Likewise, existing solutions for testing process variation delay defects use algorithms that are not targeted to small random delay defects. These techniques are unable to test all possible small random delay defects. Thus, no existing solution can efficiently test for the joint impact of parametric process variation delay defects and small random delay defects.

### SUMMARY OF THE INVENTION

In one embodiment, the invention is a method and apparatus for variation aware testing of small random delay defects. One embodiment of a method for selecting a set of paths with which to test an integrated circuit chip includes computing a metric that considers the joint impact of parametric process variation delay defects and single random delay defects and selecting the set of paths such that the value of the metric is at least as great as a target value.

### BRIEF DESCRIPTION OF THE DRAWINGS

So that the manner in which the above recited features of the present invention can be understood in detail, a more particular description of the invention may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram illustrating one embodiment of a method 100 for testing a batch of IC chips, according to the present invention;

FIG. 2 is a schematic diagram illustrating a portion of an exemplary timing graph for an integrated circuit chip;

FIG. 3 is a flow diagram illustrating one embodiment of a method for variation-aware testing for small random delay defects in an integrated circuit chip; and

FIG. 4 is a high-level block diagram of path selection method that is implemented using a general purpose computing device.

### DETAILED DESCRIPTION

In one embodiment, the present invention is a method and apparatus for variation aware testing of small random delay defects. In particular, embodiments of the present invention select a set of paths for use in at-speed testing of IC chips. This set of paths maximizes the process space coverage (which accounts for parametric process variation delays) and the topological coverage (which accounts for small random delay defects) of the at-speed test. The quality of this coverage is represented by a test quality metric Q(Π).

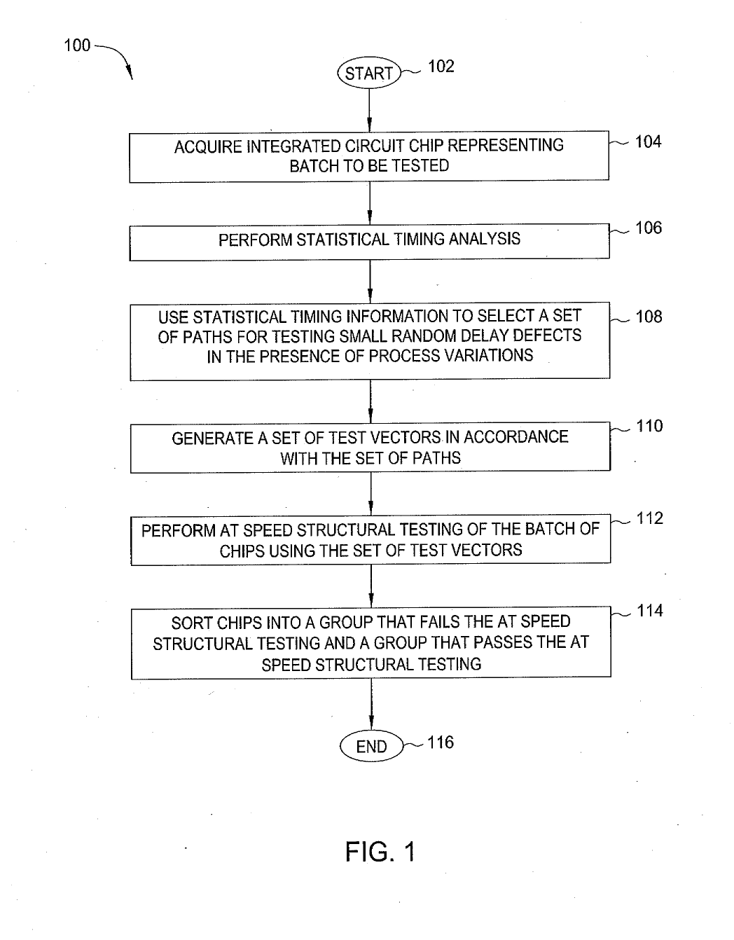

FIG. 1 is a flow diagram illustrating one embodiment of a method 100 for testing a batch of IC chips, according to the present invention. Specifically, the goal of the method 100 is to identify the chips in the batch that are “good” (i.e., pass timing requirements, which may be customer specified requirements) and the chips in the batch that are “bad” (i.e., fail timing requirements).

The method 100 is initialized at step 102 and proceeds to step 104, where a circuit representing the batch of chips to be tested is acquired. In step 106, statistical timing analysis is performed for the IC chip. The result of the statistical timing analysis is a set of statistical timing information including, but not limited to, arrival times, required arrival times, and slacks.

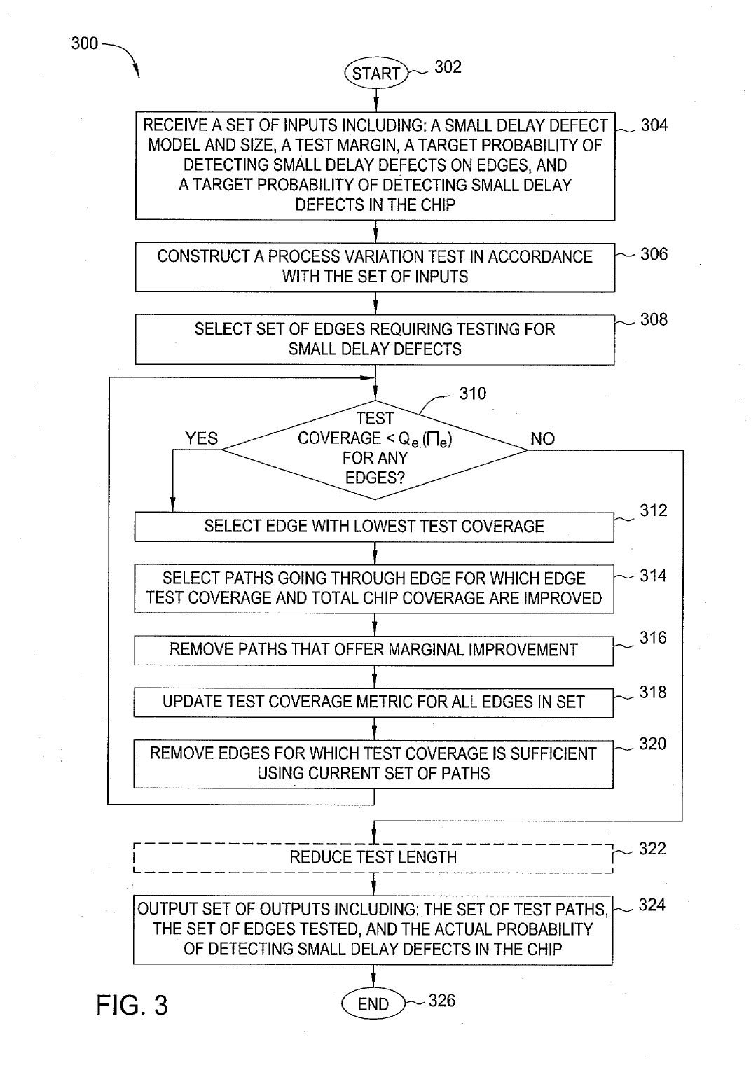

In step 108, the statistical timing information is used to select a set of paths for testing the batch of IC chips. Specifically, the set of paths is selected to test the IC chips for small random delay defects in the presence of process variations. One embodiment of a method for selecting these paths is discussed in more detail with respect to FIG. 3.

In step 110, a set of test vectors is generated in accordance with the set of paths selected in step 108. In one embodiment, the set of test vectors is generated using an automatic test pattern generation (ATPG) tool that takes the set of paths as an input.

In step 112, at speed structural testing (ASST) is performed for the batch of IC chips using the set of test vectors. Each of the IC chips will either pass ASST or fail ASST.

In step 114, the batch of IC chips is sorted into two groups: (1) a group that passes ASST; and (2) a group that fails ASST. The IC chips that pass ASST are considered “good” and are typically put into circulation, while the chips that fail ASST are considered “bad” and are typically withheld from circulation.

The method 100 then terminates in step 116.

As discussed above, a goal of the present invention is the selection of a set of paths for ASST that tests small random delay defects in the presence of process variations. Accordingly to the commonly accepted single defect model, a small random delay defect can occur only at a single location on a chip. This model is justified by the fact that the probability of a defect is very low. However, testing for single small random delay defects can detect multiple defects as well. The minimum size of a small random delay defect can be much smaller than the clock cycle. Since the location of this small random delay defect can be anywhere on the chip, testing small random delay defects is also referred to as “topological coverage.”

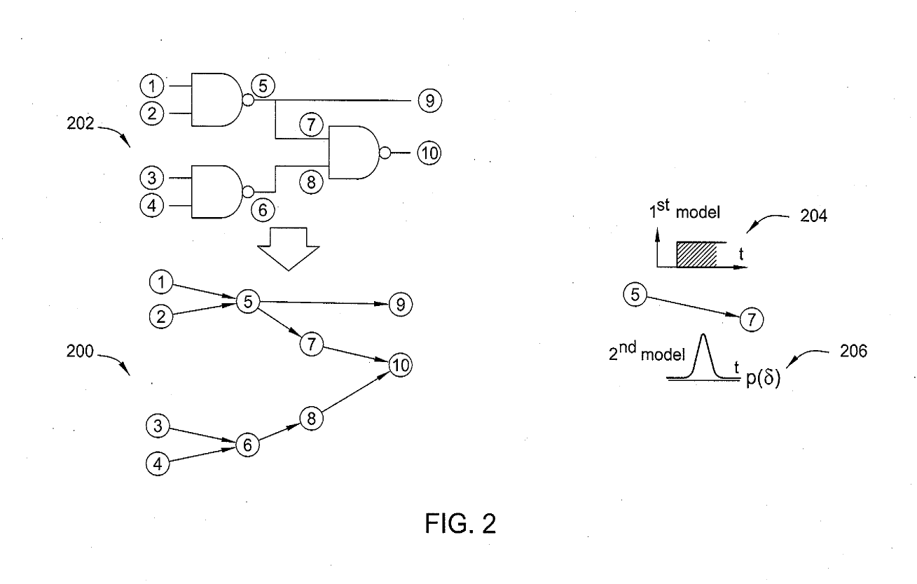

FIG. 2, for example, is a schematic diagram illustrating a portion of an exemplary timing graph 200 for an integrated circuit chip. The exemplary timing graph 200 is derived from a net list 202 and includes a plurality of nodes (designated by the numerals 1-10), which represent the inputs, outputs, and internal nodes of the corresponding integrated circuit chip. The nodes are connected to each other by timing edges, which represent gates and wires (signal propagation paths) between gates. Thus, gate and wire delays are represented as timing edge delays. Those skilled in the art will recognize that FIG. 2 illustrates only one way of modeling the net list with a timing graph.

Small random delay defects are associated with edge delays. Thus, a small random delay defect can happen at either a gate or a wire. In the example illustrated in FIG. 2, a small random delay defect is present on the edge connecting node 5 and node 7. In one embodiment, the present invention models small random delay defects in one of two ways. The first method of modeling the delay due to the small random delay defect δ is as an arbitrarily large delay change that is no smaller than a specified minimum value, which may be represented as either a constant or a fraction of the gate/wire delay, or a fraction of the clock cycle. The chart 204 illustrates this first method of modeling the delay due to the small random delay defect δ. The second method of modeling the delay due to the small random delay defect δ is as a random variable with a known distribution p(δ). The chart 206 illustrates this second method of modeling the delay due to the small random delay defect δ. The simplest model of a small random delay defect is typically a defect of constant size (e.g., according to the first method). In addition to the small random delay defect δ, the delays of all gates and wires are affected by process variations. The gates and wires will have different sensitivities to different process parameters.

As discussed above, the quality of the coverage of a set of test paths is represented according to the invention by a test quality metric Q(Π), where Π is the set of test paths. This test quality metric Q(Π) is perhaps best understood by first applying the metric to a single timing edge. Within the context of a single timing edge, the test quality metric describes the probability that the timing of a given IC chip is good (i.e., will satisfy customer specifications with a positive chip slack S_{C}), conditional upon: (1) the chip gates and wires being affected by process variation; (2) the timing edge of interest having a single small random delay defect; and (3) the chip passing testing. Thus, the test quality metric Qₑ(Πₑ) for a single edge e (where the delay due to the small random delay defect is modeled as an arbitrarily large change in delay) can be expressed as:

Qₑ(Πₑ)=P(S_{C}≧0|S_{T}>T_{M},Dₑ=D+δ) (EQN. 1)

where S_{C} is the timing slack of the chip, S_{T} is the timing slack of the test path (i.e., the timing slack of the paths under the test condition), T_{M} is the test margin (which is related to the test clock frequency), Πₑ is the set of test paths through the edge e, Dₑ is the delay on the edge e, and D is the delay due to process variation. Many of these timing quantities (e.g., slacks, delays) are obtained through statistical timing analysis of the IC chip. Thus, the test quality metric Qₑ(Πₑ) describes the probability that the chip slack on the edge e is greater than or equal to zero when: (1) the timing slack of the test path is greater than the test margin; and (2) the delay on the edge is equal to the process variation delay plus the delay of the small random delay defect; and (3) the delays of other edges are affected by process variation.

The test quality metric Qₑ(Πₑ) for a small random delay defect that is modeled as a random variable (with its distribution given as p(δ)) is similarly expressed as:

$${Q}_{e} ( {Π}_{e} ) = {{\int }_{- ∞}}^{∞} P ( {S}_{C} \geq 0 \vert {S}_{T} > {T}_{M} , {D}_{e} = D + δ ) p ( δ ) d δ \qquad ( EQN . 2 )$$

For a set of test paths (where each path comprises at least one edge), the full test quality metric Q(Π) describes the probability that the timing of a given IC chip is good, conditional upon: (1) the chip gates and wires being affected by process variation; (2) a single small random delay defect exists within the set of test paths; and (3) the set of test paths passing testing. If the probability of a single small random delay defect on the edge e is pₑ, then the test quality metric for the IC chip can be expressed as:

$$Q ( Π ) = {\sum }_{e ∈ E} {p}_{e} {Q}_{e} ( {Π}_{e} ) where {\sum }_{e ∈ E} {p}_{e} = 1 , \qquad ( EQN . 3 )$$

and E is the set of all edges in the set of test paths Π. If all edges have an equal probability of failing, then pₑ=1/Nₑ, and the test quality metric may be expressed as:

$$Q ( Π ) = {\sum }_{e ∈ E} {p}_{e} {Q}_{e} ( {T}_{e} ) = \frac{{\sum }_{e ∈ E} {Q}_{e} ( {T}_{e} )}{{N}_{e}} \qquad ( EQN . 4 )$$

As discussed above, the test quality metric, is implemented in a method that selects a set of paths that may subsequently be fed to an automatic test pattern generation (ATPG) tool. The ATPG tool then generates a set of test patterns that are used to test a batch of IC chips. Chips that pass the testing are considered “good” chips and are put into circulation, while chips that fail the testing are considered “bad” chips and are withheld from circulation.

FIG. 3 is a flow diagram illustrating one embodiment of a method 300 for variation-aware testing for small random delay defects in an integrated circuit chip. Specifically, the method 300 selects a set of paths for at-speed testing (e.g., in accordance with step 108 of the method 100), where the set of test paths maximizes the process space coverage and the topological coverage of the test (i.e., small random delay defect coverage).

The method 300 is initialized at step 302 and proceeds to step 304, where a set of inputs is received. In one embodiment, these inputs include: (1) a small random delay defect model δ and defect size (e.g., as discussed above with respect to FIG. 1); (2) a test margin T_{M} (i.e., an additional timing performance demanded of the tester, which can reduce the test length and search space at the expense of some yield loss); (3) a target probability of detecting small random delay defects on edges (e.g., x % of the defects should be detected); and (4) a target test quality metric value for the total chip coverage.

In step 306, a process variation test is constructed in accordance with the set of inputs received in step 304. In one embodiment, the variation of each process parameter is modeled as a random variable ΔXₖ. For K number of process parameters, the corresponding random variables jointly form a K-dimensional space Ω=R^{K}. The impact of process variation on timing is modeled by denoting the path slack S of a path as a function of these process parameters. In other words, S=F(ΔXₖ). Depending on each chip's manufacturing conditions (i.e., the particular setting of each process parameter), the same path will exhibit different slacks on different chips. One method for constructing a process variation test is discussed in greater detail in co-pending, commonly assigned U.S. patent application Ser. No. 12/111,634, filed Apr. 29, 2008, which is herein incorporated by reference in its entirety.

In step 308, a set of edges E requiring testing for small random delay defects is selected. Then, in step 310, a determination is made as to whether the test coverage is insufficient (i.e., Qₑ(Πₑ)<target probability of detecting small random delay defects on edges)) for any of the edges in the set E.

If it is determined in step 310 that there is an edge for which the test coverage is insufficient, then the method 300 proceeds to step 312. In step 312, the edge e with the lowest test coverage in the set is selected.

In step 314, a set of paths π going through the edge e that improves the edge test coverage and the total chip coverage is selected. This set of paths is added to the complete set of test paths Π to be used in testing. In one embodiment, this set of paths it is selected using a branch and bound algorithm, for example as discussed in application Ser. No. 12/111,634. The test quality metrics reflecting both the edge test coverage Qₑ(Πₑ) and the total test coverage Q(Π) guide selection of the set of paths. In one embodiment, the set of paths it is selected to improve the edge test coverage Qₑ(Πₑ) up to the target probability of detecting small random delay defects on edges.

In step 316, paths that provide only marginal improvement of the edge test coverage are removed from the set of paths π. In one embodiment, this involves comparing the paths in the set of paths π with the paths in the complete set of test paths Π to be used in testing.

In step 318, the edge test coverage Qₑ(Πₑ) is updated in accordance with the set of paths π (e.g., using EQNs. 1 and/or 2).

In step 320, any edges in the set of edges E for which the test coverage is sufficient using the complete set of test paths Π are removed from the set of edges E. The method 300 then returns to step 310, where the determination is again made as to whether the test coverage is insufficient for any of the edges in the set E.

If it is determined in any iteration of step 310 that there are no edges in the set of edges E for which the test coverage is insufficient, then the method 300 proceeds directly to step 322. In optional step 322, the length of the test is reduced. In one embodiment, the test length is reduced by adjusting the test margin T_{M}. In another embodiment, the test length is reduced by eliminating paths from the complete set of test paths Π that do not sufficiently contribute to the test coverage (e.g., redundant paths).

In step 324, a set of outputs is outputted (e.g., to an ATPG tool). In one embodiment, the set of outputs includes: (1) a set of test paths Π; (2) a set of edges tested E (where the actual probabilities of the edge testing are represented by the edge test quality metric Qₑ(Πₑ)); and (3) the actual probability of detecting small random delay defects in the chip (represented by the chip test quality metric Q(Π)). The method 300 then terminates in step 326.

The test slack of the selected set of test paths Π is denoted as S_{T}. In one embodiment, Π is the set of paths selected for process variation test in step 306 only. In another embodiment, Π includes both the set of paths selected for process variation test in step 306 and the set of paths selected so far in step 314 to cover small random delay defects.

The set of test paths Π can be divided into two groups: (1) the set of test paths going through the edge e; and (2) the set of test paths not going through the edge e. Accordingly, the test slack (i.e., the minimum slack of all test paths) can be expressed as:

S_{T}=min(S_{Π}_{ₑ},S_{Π}_{_{\tilde{e}}}) (EQN. 5)

where S_{Π}_{ₑ} is the edge test slack (i.e., the slack of the test paths going through the edge e), and S_{Π}_{_{\tilde{e}}} is the Complement Edge Test Slack (i.e., the Slack of the Test Paths not going through the edge e).

As discussed above, the path selection method 300 relies in part on the edge test coverage metric Qₑ(Πₑ). This metric represents the probability that the edge slack is positive conditional upon: (1) the existence of a small random delay defect on an edge; and (2) the chip passing testing. The test paths going through the edge and the test paths not going through the edge are considered separately.

The quality metric Qₑ(Πₑ) can be computed as:

$$\begin{matrix}{Q}_{e} ( {Π}_{e} ) = P ( {S}_{C} \geq 0 \vert {S}_{T} > {T}_{M} , {D}_{e} = D + δ ) \\ = P ( {S}_{e} \geq 0 , {S}_{\tilde{e}} \geq 0 \vert {S}_{T} > {T}_{M} , {D}_{e} = D + δ )\end{matrix} \qquad ( EQN . 6 )$$

where Sₑ is the edge slack (i.e., the minimum slack of all paths going through the edge e), S_{\tilde{e}} is the complement edge slack (i.e., the minimum slack of all paths not going through the edge e), and the chip slack S_{C}=min(Sₑ,S_{\tilde{e}}), by definition.

In one embodiment, the following formula can be used to compute Qₑ(Πₑ):

$$\begin{matrix}{Q}_{e} ( {Π}_{e} ) = P ( {S}_{C} \geq 0 \vert {S}_{{Π}_{e}} > {T}_{M} , {S}_{{Π}_{\tilde{e}}} > {T}_{M} , {D}_{e} ( δ ) = D + δ ) \\ = \frac{P ( {S}_{e} > 0 , {S}_{\tilde{e}} > 0 , {S}_{{Π}_{e , 0}} - δ > {T}_{M} , {S}_{{Π}_{\tilde{e} , 0}} > {T}_{M} )}{P ( {S}_{{Π}_{e , 0}} - δ > {T}_{M} , {S}_{{Π}_{\tilde{e} , 0}} > {T}_{M} )} \\ = \frac{P ( \begin{matrix}{S}_{e , 0} - δ > 0 , {S}_{\tilde{e} , 0} > 0 , {S}_{{Π}_{e , 0}} - δ - {T}_{M} > 0 , \\ {S}_{{Π}_{\tilde{e} , 0}} - {T}_{M} > 0\end{matrix} )}{P ( {S}_{{Π}_{e , 0}} - δ - {T}_{M} > 0 , {S}_{{Π}_{\tilde{e} , 0}} - {T}_{M} > 0 )} \\ = \frac{P ( MIN ( {S}_{e , 0} - δ , {S}_{\tilde{e} , 0} , {S}_{{Π}_{e , 0}} δ - {T}_{M} , {S}_{{Π}_{\tilde{e} , 0}} - {T}_{M} ) > 0 )}{P ( MIN ( {S}_{{Π}_{e , 0}} - δ - {T}_{M} , {S}_{{Π}_{\tilde{e} , 0}} - {T}_{M} ) > 0 )}\end{matrix} \qquad ( EQN . 7 )$$

where S_{e,0}, S_{\tilde{e},0}, S_{Π}_{_{e,0}}, and S_{Π}_{_{\tilde{e},0}} are the edge slack, the complement edge slack, the edge test slack, and the complement edge test slack, respectively, all in the absence of small random delay defect δ. All of these quantities are obtainable from the parameterized statistical timing analysis in the absence of small random delay defects. Note that S_{\tilde{e},0}=S_{\tilde{e}} (i.e., the complement edge slack does not change in the presence of a small random delay defect at edge e).

In another embodiment, the computation of Qₑ(Πₑ) can be simplified as:

Qₑ(Πₑ)=P(S_{w}≧0|S_{T}>T_{M},Dₑ=D+δ) (EQN. 8)

because

P(S_{\tilde{e}}≧0|S_{T}>T_{M},Dₑ=D+δ)≈1 (EQN. 9)

for the given set of paths that includes paths selected for process variation test in step 306.

Hence, the following formula can be used to compute Qₑ(Πₑ) for efficiency:

$$\begin{matrix}{Q}_{e} ( {Π}_{e} ) = P ( {S}_{e} \geq 0 \vert {S}_{{Π}_{e}} > {T}_{M} , {S}_{{Π}_{\tilde{e}}} > {T}_{M} , {D}_{e} ( δ ) = D + δ ) \\ = \frac{P ( {S}_{e , 0} - δ > 0 , {S}_{{Π}_{e , 0}} - δ > {T}_{M} , {S}_{{Π}_{\tilde{e} , 0}} > {T}_{M} )}{P ( {S}_{{Π}_{e , 0}} - δ > {T}_{M} , {S}_{{Π}_{\tilde{e} , 0}} > {T}_{M} )} \\ = \frac{P ( {S}_{e , 0} - δ > 0 , {S}_{{Π}_{e , 0}} - δ - {T}_{M} > 0 , {S}_{{Π}_{\tilde{e} , 0}} - {T}_{M} > 0 )}{P ( {S}_{{Π}_{e , 0}} - δ - {T}_{M} > 0 , {S}_{{Π}_{\tilde{e} , 0}} - {T}_{M} > 0 )} \\ = \frac{P ( MIN ( {S}_{e , 0} - δ , {S}_{{Π}_{e , 0}} - δ - {T}_{M} , {S}_{{Π}_{\tilde{e} , 0}} - {T}_{M} ) > 0 )}{P ( MIN ( {S}_{{Π}_{e , 0}} - δ - {T}_{M} , {S}_{{Π}_{\tilde{e} , 0}} - {T}_{M} ) > 0 )}\end{matrix} \qquad ( EQN . 10 )$$

where S_{e,0}, S_{Π}_{_{e,0}}, and S_{Π}_{_{\tilde{e},0}} are the edge slack, the edge test slack, and the complement edge test slack, respectively, all in the absence of small random delay defect δ. All of these quantities are obtainable from the parameterized statistical timing analysis in the absence of small random delay defects.

Each edge is associated with an edge test coverage. Each edge also refers to a set of test paths that test this edge. However, the same paths also test small random delay defects of the other edges belonging to these paths. Thus, the metric for path test quality for path selection can be computed as a weighted sum of the edge test coverage and the total path quality metric of this set of paths. In one embodiment, the metric Q for path test quality for path selection is computed as:

Q=α·Qₑ+β·Q_{P} (EQN. 11)

where α and β are weights, Qₑ is the edge test quality metric, and Q_{P} is the path test quality metric. EQN. 11 takes into account a path's capability to test both an edge of interest and other edges of the path.

Thus, the path quality metric for edge test coverage describes the edge test coverage by a given path. The improvement of the individual test quality metric of a path quality may be compared relative to the improvement over the process variation test and/or the improvement over all test paths accumulated at a given time.

The total path quality metric, Q_{P} comprises a first probability that is computed as the sum of the edge test coverage metrics (i.e., a set of second probabilities) for all edges of the path to be tested, or:

$${Q}_{P} = {\sum }_{e ∈ P} {Q}_{e} ( {T}_{P , e} , δ ) \qquad ( EQN . 12 )$$

The total path quality metric, Q_{P} can also be divided by the number of edges for normalization purposes.

Thus, once one has a well-defined test quality metric, one can evaluate the goodness of testing of any given set of test paths. This allows the best paths to be selected to maximize the test quality metric. Any one or more of a number of path selection techniques may be improved using this test quality metric. Path selection may additionally consider: node criticalities (e.g., statistical projected slack, critical probability, probability of chip timing degradation in the presence of a single random defect delay, probability of a single random defect delay not being tested when it causes a timing violation, or probability of a node improving a test quality metric), the spatial coverage of timing points, the integration with ATPG to guarantee path sensitizability, path redundancy, and total path selection number.

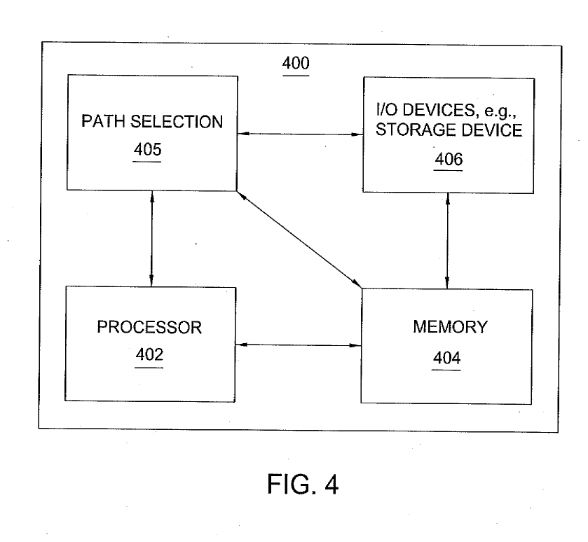

FIG. 4 is a high-level block diagram of path selection method that is implemented using a general purpose computing device 400. In one embodiment, a general purpose computing device 400 comprises a processor 402, a memory 404, a path selection module 405 and various input/output (I/O) devices 406 such as a display, a keyboard, a mouse, a stylus, a wireless network access card, and the like. In one embodiment, at least one I/O device is a storage device (e.g., a disk drive, an optical disk drive, a floppy disk drive, a path selection tool, and/or a test pattern generation tool). It should be understood that the path selection module 405 can be implemented as a physical device or subsystem that is. coupled to a processor through a communication channel.

Alternatively, the path selection module 405 can be represented by one or more software applications (or even a combination of software and hardware, e.g., using Application Specific Integrated Circuits (ASIC)), where the software is loaded from a storage medium (e.g., I/O devices 406) and operated by the processor 402 in the memory 404 of the general purpose computing device 400. Thus, in one embodiment, the path selection module 405 for variation aware testing of small random delay defects, as described herein with reference to the preceding Figures, can be stored on a computer readable storage device (e.g., RAM, magnetic or optical drive or diskette, and the like).

It should be noted that although not explicitly specified, one or more steps of the methods described herein may include a storing, displaying and/or outputting step as required for a particular application. In other words, any data, records, fields, and/or intermediate results discussed in the methods can be stored, displayed, and/or outputted to another device as required for a particular application. Furthermore, steps or blocks in the accompanying Figures that recite a determining operation or involve a decision, do not necessarily require that both branches of the determining operation be practiced. In other words, one of the branches of the determining operation can be deemed as an optional step.

While the foregoing is directed to embodiments of the present invention, other and further embodiments of the invention may be devised without departing from the basic scope thereof. Various embodiments presented herein, or portions thereat may be combined to create further embodiments. Furthermore, terms such as top, side, bottom, front, back, and the like are relative or positional terms and are used with respect to the exemplary embodiments illustrated in the figures, and as such these terms may be interchangeable.

What is claimed is:

1. A method for selecting a set of paths with which to test an integrated circuit chip, the method comprising:
computing a metric that considers a joint impact of at least one parametric process variation delay defect and at least one single random delay defect; and
selecting the set of paths such that a value of the metric is at least as great as a target value,
wherein at least one of the computing or the selecting is performed by a processor.

2. The method of claim 1, wherein each of the at least one parametric process variation delay defect is a defect due to variation of at least one process parameter that is applicable to the integrated circuit chip.

3. The method of claim 1, wherein each of the at least one single random delay defect occurs at a single location in the integrated circuit chip.

4. The method of claim 1, wherein the at least one single random delay defect is augmented with a delay due to at least one of the at least one parametric process variation delay defect.

5. The method of claim 1, wherein the metric is computed using values obtained from statistical timing analysis of the integrated circuit chip.

6. The method of claim 1 wherein a delay due to the at least one single random delay defect is modeled as an arbitrarily large delay change that is no smaller than a specified value.

7. The method of claim 6, wherein the arbitrarily large delay change is represented as a constant.

8. The method of claim 6, wherein the arbitrarily large delay change is represented as a fraction of a gate delay or a wire delay.

9. The method of claim 6, wherein the arbitrarily large delay change is represented as a fraction of a clock cycle.

10. The method of claim 1 wherein a delay due to the at least one single random delay defect is modeled as a random variable with a known distribution.

11. The method of claim 1, wherein the metric comprises a first probability that a timing of the integrated circuit chip will pass customer specified requirements conditional upon: at least one gate and at least one wire of the integrated circuit chip being affected by the at least one parametric process variation delay defect, an existence of the at least one single random delay defect within the set of paths, and the set of test paths passing testing.

12. The method of claim 11, wherein the first probability comprises a sum of a second probability for a set of edges in the set of paths.

13. The method of claim 12, wherein the second probability for a given edge in the set of edges comprises a probability that the timing of the integrated circuit chip will pass timing requirements conditional upon: at least one gate and at least one wire of the integrated circuit chip being affected by the at least one parametric process variation delay defect, an existence of the at least one single random delay defect on the given edge, and the set of test paths passing testing.

14. The method of claim 13, wherein the second probability for the given edge comprises a probability that a chip slack is greater than or equal to zero when: a timing slack of all test paths is greater than a test margin and a delay on the edge is equal to a delay due to the at least one parametric process variation delay defect plus a delay due to the at least one single random delay defect.

15. The method of claim 1, wherein the selecting comprises:
constructing a process variation test for the integrated circuit chip;
selecting a set of edges in the integrated circuit chip requiring testing for the at least one single random delay defect; and
selecting the set of paths such that the set of paths go through edges in the set of edges and improve a value of the metric.

16. The method of claim 15, wherein the value of the metric is improved if the value of the metric is closer to a target value.

17. The method of claim 15, wherein the set of paths is selecting using a branch and bound technique.

18. The method of claim 1, further comprising:
outputting the set of paths, a set of edges tested in the set of test paths, and a value of the metric calculated in accordance with the set of paths and the set of edges.

19. A computer readable storage device containing an executable program for selecting a set of paths with which to test an integrated circuit chip, where the program performs steps of:
computing a metric that considers a joint impact of at least one parametric process variation delay defect and at least one single random delay defect; and
selecting the set of paths such that a value of the metric is at least as great as a target value.

20. Apparatus for selecting a set of paths with which to test an integrated circuit chip, the apparatus comprising:
means for computing a metric that considers a joint impact of at least one parametric process variation delay defect and at least one single random delay defect; and
means for selecting the set of paths such that a value of the metric is at least as great as a target value.
